(19) United States
(12) Patent Application Publication
(10) Pub. No.: US 2026/0300567 A1
(43) Pub. Date: Oct. 1, 2026

(54) MODEL-BASED BUILDING WORKFLOW ORCHESTRATION

(71) Applicant: Tyco Fire & Security GmbH, Neuhausen am Rheinfall (CH)

(72) Inventors: Arun Mathew, Frankin, MA (US); Eric Michael Augustine, Greendale, WI (US); Michael James Risbeck, West Chester, OH (US); Aditya Gundawar, Pune (IN)

(21) Appl. No.: 19/577,109

(22) Filed: Mar. 24, 2026

Related U.S. Application Data
(60) Provisional application No. 63/777,284, filed on Mar. 25, 2025.

(51) Int. Cl. G06F 30/13; G06F 30/27

(52) U.S. Cl. CPC G06F 30/13; G06F 30/27

(57) ABSTRACT

One or more aspects relate to a system for configurating building workflows. The system includes one or more memory devices storing instructions thereon that, when executed by one or more processors, cause the one or more processors to receive a request associated with operation of a building asset, select, based on the request, one or more applications to be executed to address the request, cause generation of commands representing a sequence of operations for the one or more applications to address the request, and instruct the one or more applications to address the request based on the commands.

### CROSS-REFERENCE TO RELATED APPLICATIONS

This application claims the benefit of and priority to U.S. Provisional Patent Application No. 63/777,284 filed Mar. 25, 2025, which is incorporated herein by reference in its entirety.

### BACKGROUND

This application relates generally to a building system of a building. This application relates more particularly to systems for managing and processing data relating to assets of the building system.

Some building workflow configurations involve manually deploying applications or other software to complete requests relating to building assets. Responses to requests may be pre-constructed (e.g., templated) and not customized to the requirements of the end-user.

### SUMMARY

One or more aspects relate to a system for configurating building workflows. The system includes one or more memory devices storing instructions thereon that, when executed by one or more processors, cause the one or more processors to receive a request associated with operation of a building asset, select, based on the request, one or more applications to be executed to address the request, cause generation of commands representing a sequence of operations for the one or more applications to address the request, and instruct the one or more applications to address the request based on the commands.

At least one aspect relates to the system, wherein the commands are generated by an artificial intelligence model, and wherein the instructions cause the one or more processors to receive a response from the one or more applications, the response including information associated with addressing the request, determine, based on the response, whether the request was resolved, and update at least one of (a) the artificial intelligence model or (b) the one or more applications based on the determination of whether the request was resolved.

At least one aspect relates to the system, wherein the instructions cause the one or more processors to store the request and the response in a request repository, and cause the request and the response to be displayed on a user interface.

At least one aspect relates to the system, wherein the instructions cause the one or more processors to determine whether the request is of a valid type, and determine whether the one or more applications were successful in addressing the request.

At least one aspect relates to the system, wherein instructions cause the one or more processors to receive the request responsive to at least one of (i) a transmission of the request caused by an interaction with a user interface, or (ii) a transmission of the request transmitted by the building asset.

At least one aspect relates to the system, wherein the instructions cause the one or more processors to select the one or more applications by identifying, based on the request, the one or more applications from an application repository to be executed to address the request, and retrieving, from the application repository, the one or more applications.

At least one aspect relates to the system, wherein the instructions cause the one or more processors to cause generation of commands by generating an prompt for an artificial intelligence model, the prompt indicating the request and the one or more applications, and transmitting the prompt to the artificial intelligence model.

At least one aspect relates to the system, wherein the instructions cause the one or more processors to instruct the one or more applications by receiving the commands representing a sequence of operations from an artificial intelligence model, and generating, based on the commands, an instruction for the one or more applications to address the request.

At least one aspect relates to the system, wherein the request includes identifying information associated with the one or more applications.

At least one aspect relates to the system, wherein the one or more applications include a plurality of application versions, wherein the instructions cause the one or more processors to select the one or more applications based on the plurality of application versions, and instruct the one or more applications to address the request based on the selected application version.

One or more aspects relate to a method of building language model workflow configuration. The method includes receiving, by one or more processors, a request associated with operation of a building asset, selecting, by the one or more processors, based on the request, one or more applications to be executed to address the request, causing, by the one or more processors, generation of commands representing a sequence of operations for the one or more applications to address the request, and instructing, by the one or more processors, the one or more applications to address the request based on the commands.

At least one aspect relates to the method, further including determining, by the one or more processors, whether the request is of a valid type, and determining, by the one or more processors, whether the one or more applications were successful in addressing the request.

At least one aspect relates to the method, wherein selecting the one or more applications includes identifying, by the one or more processors, based on the request, the one or more applications to be executed to address the request, and retrieving, by the one or more processors, the one or more applications.

At least one aspect relates to the method, wherein causing generation of commands includes generating, by the one or more processors, an prompt for an artificial intelligence model, the prompt indicating the request and the one or more applications, and transmitting, by the one or more processors, to the artificial intelligence model, the prompt.

At least one aspect relates to the method, wherein the commands are generated by an artificial intelligence model, further including: receiving, by the one or more processors, a response from the one or more applications, the response including information associated with addressing the request, determining, by the one or more processors, based on the response, whether the request was resolved, and updating, by the one or more processors, the artificial intelligence model based on the determination of whether the request was resolved.

At least one aspect relates to the method, wherein instructing the one or more applications includes receiving, by the one or more processors, the commands representing a sequence of operations from the artificial intelligence model, and generating, by the one or more processors, based on the commands, an instruction for the one or more applications to address the request.

At least one aspect relates to the method, further including storing, by the one or more processors, the request and the response in a request repository, and causing, by the one or more processors, the request and the response to be displayed on a user interface.

One or more aspects relate to one or more non-transitory storage media storing instructions thereon that, when executed by one or more processors, cause the one or more processors to perform operations including receive a request associated with operation of a building asset, select, based on the request, one or more applications to be executed to address the request, cause generation of commands representing a sequence of operations for the one or more applications to address the request, and instruct the one or more applications to address the request based on the commands.

At least one aspect relates to the one or more non-transitory storage media, wherein the instructions cause the one or more processors to cause generation of commands by generating an prompt for an artificial intelligence model, the prompt indicating the request and the one or more applications, and transmitting the prompt to the artificial intelligence model.

At least one aspect relates to the one or more non-transitory storage media, wherein the commands are generated by an artificial intelligence model, and wherein the instructions cause the one or more processors to receive a response from the one or more applications, the response including information associated with addressing the request, determine, based on the response, whether the request was resolved, and update the artificial intelligence model based on the determination of whether the request was resolved.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a block diagram of an example of a machine learning model-based system for building workflow orchestration.

FIG. 2 is a block diagram of an example of a language model-based system for building workflow orchestration.

FIG. 3 is a block diagram of an example of a building workflow orchestration system.

FIG. 4 is an example block diagram of a process for handling requests using the building workflow orchestration system of FIG. 3.

FIG. 5 is an example block diagram of a process for completing requests using the building workflow orchestration system of FIG. 3.

FIG. 6 is an example method for completing a request using the workflow orchestration system of FIG. 3.

FIG. 7 is an example method for completing a request using the workflow orchestration system of FIG. 3.

### DETAILED DESCRIPTION

Referring generally to the FIGURES, systems and methods in accordance with the present disclosure can facilitate (e.g., control, organize, assign, etc.) building workflows. Building workflows can involve orchestration between multiple components of a building, including but not limited to sensors, controllers, and/or other equipment that impact the environment within the building, such as heating, ventilation, and air conditioning (HVAC), lighting, security, fire protection, and/or access control equipment. In some instances, building workflows can depend on static and/or hard-coded data processing of upstream components, such as parsing data structures storing sensor data from sensors, or configuring commands in control signals sent from controllers to components based on the sensor data. This can limit the ability of building management systems to adapt to edge cases, or to automatically integrate updated or new components into a building workflow.

Systems and methods in accordance with the present disclosure can use language models, such as large language models (LLMs), to more effectively configure and/or update building workflows. For example, using the ability of LLMs to interpret and produce natural language, it can be beneficial to implement a language model-based workflow orchestration system capable of retrieving relevant data, handling preprocessing of data, running platform applications, and/or producing structured or summarized responses of outputs. These capabilities may facilitate the ability of certain applications to be deployed within building workflows, including applications that integrate and use artificial intelligence (AI) models. For example, systems and methods described herein can facilitate generation and execution of dynamic workflows involving available building components without static parsing of data structures and/or manual deployment, and can allow for greater compatibility amongst building components to be operated in an electronic workflow. As another example, systems and methods described herein can generate custom responses to user requests, without resorting to pre-generated templates.

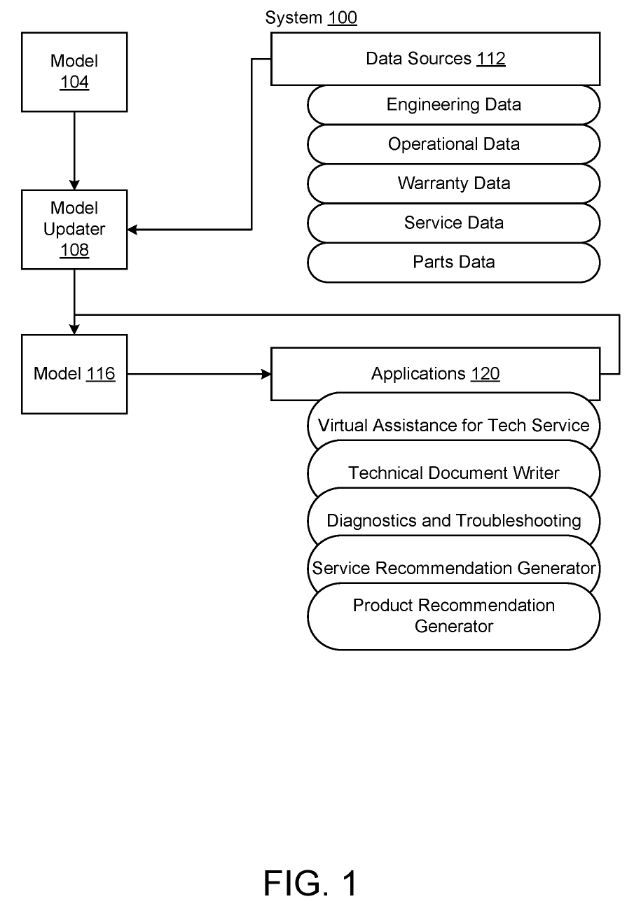

FIG. 1 depicts an example of a system 100. The system 100 can implement various operations for configuring (e.g., training, updating, modifying, transfer learning, fine-tuning, etc.) and/or operating various AI and/or ML systems, such as neural networks of LLMs or other generative AI systems. The system 100 can be used to implement various generative AI-based building equipment servicing operations.

For example, the system 100 can be implemented for operations associated with any of a variety of building management systems (BMSs) or equipment or components thereof. A BMS can include a system of devices that can control, monitor, and manage equipment in or around a building or building area. The BMS can include, for example, a HVAC system, a security system, a lighting system, a fire alerting system, any other system that is capable of managing building functions or devices, or any combination thereof. The BMS can include or be coupled with items of equipment, for example and without limitation, such as heaters, chillers, boilers, air handling units, sensors, actuators, refrigeration systems, fans, blowers, heat exchangers, energy storage devices, condensers, valves, or various combinations thereof. The items of equipment can operate in accordance with various qualitative and quantitative parameters, variables, setpoints, and/or thresholds or other criteria, for example. In some instances, the system 100 and/or the items of equipment can include or be coupled with one or more controllers for controlling parameters of the items of equipment, such as to receive control commands for controlling operation of the items of equipment.

Various components of the system 100 or portions thereof can be implemented by one or more processors coupled with or more memory devices (memory). The processors can be a general purpose or specific purpose processors, an application specific integrated circuit (ASIC), one or more field programmable gate arrays (FPGAs), a group of processing components, or other suitable processing components. The processors may be configured to execute computer code and/or instructions stored in the memories or received from other computer readable media (e.g., CDROM, network storage, a remote server, etc.). The processors can be configured in various computer architectures, such as graphics processing units (GPUs), distributed computing architectures, cloud server architectures, client-server architectures, or various combinations thereof. One or more first processors can be implemented by a first device, such as an edge device, and one or more second processors can be implemented by a second device, such as a server or other device that is communicatively coupled with the first device and may have greater processor and/or memory resources. The memories can include one or more devices (e.g., memory units, memory devices, storage devices, etc.) for storing data and/or computer code for completing and/or facilitating the various processes described in the present disclosure. The memories can include random access memory (RAM), read-only memory (ROM), hard drive storage, temporary storage, non-volatile memory, flash memory, optical memory, or any other suitable memory for storing software objects and/or computer instructions. The memories can include database components, object code components, script components, or any other type of information structure for supporting the various activities and information structures described in the present disclosure. The memories can be communicably connected to the processors and can include computer code for executing (e.g., by the processors) one or more processes described herein.

The system 100 can include or be coupled with one or more first models 104. The first model 104 can include one or more neural networks, including neural networks configured as generative models. For example, the first model 104 can predict or generate new data (e.g., artificial data; synthetic data; data not explicitly represented in data used for configuring the first model 104). The first model 104 can generate any of a variety of modalities of data, such as text, speech, audio, images, and/or video data. The neural network can include a plurality of nodes, which may be arranged in layers for providing outputs of one or more nodes of one layer as inputs to one or more nodes of another layer. The neural network can include one or more input layers, one or more hidden layers, and one or more output layers. Each node can include or be associated with parameters such as weights, biases, and/or thresholds, representing how the node can perform computations to process inputs to generate outputs. The parameters of the nodes can be configured by various learning or training operations, such as unsupervised learning, weakly supervised learning, semi-supervised learning, or supervised learning.

The first model 104 can include, for example and without limitation, one or more language models, LLMs, attention-based neural networks, transformer-based neural networks, generative pretrained transformer (GPT) models, bidirectional encoder representations from transformers (BERT) models, encoder/decoder models, sequence to sequence models, autoencoder models, generative adversarial networks (GANs), convolutional neural networks (CNNs), recurrent neural networks (RNNs), diffusion models (e.g., denoising diffusion probabilistic models (DDPMs), latent diffusion models), or various combinations thereof. In some implementations, the first model 104 can be configured using various unsupervised and/or supervised training operations. The first model 104 can be configured using training data from various domain-agnostic and/or domain-specific data sources, including but not limited to various forms of text, speech, audio, image, and/or video data, or various combinations thereof.

The system 100 can configure the first model 104 to determine one or more second models 116. For example, the system 100 can include a model updater 108 that configures (e.g., trains, updates, modifies, fine-tunes, etc.) the first model 104 to determine the one or more second models 116. In some implementations, the second model 116 can be used to provide application-specific outputs, such as outputs having greater precision, accuracy, or other metrics, relative to the first model, for targeted applications. The second model 116 can be similar to the first model 104. For example, the second model 116 can have a similar or identical backbone or neural network architecture as the first model 104. In some implementations, the first model 104 and the second model 116 each include generative AI machine learning models, such as LLMs (e.g., GPT-based LLMs) and/or diffusion models or GANs. The second model 116 can be configured using processes analogous to those described for configuring the first model 104.

The model updater 108 can configure the second models 116 using the data from the data sources 112. For example, the model updater 108 can perform various updating, optimization, retraining, reconfiguration, fine-tuning, or transfer learning operations, or various combinations thereof, to determine the second models 116. The model updater 108 can configure the second models 116, using the data sources 112, to generate outputs (e.g., completions) in response to receiving inputs (e.g., prompts), where the inputs and outputs can be analogous to data of the data sources 112.

The system 100 can use outputs of the one or more second models 116 to implement one or more applications 120. For example, the second models 116, having been configured using data from the data sources 112, can be capable of precisely generating outputs that represent useful, timely, and/or real-time information for the applications 120. The applications 120 can include user interfaces, dashboards, wizards, checklists, virtual assistant, conversational interfaces, chatbots, configuration tools, or various combinations thereof. The applications 120 can receive an input, such as a prompt (e.g., from a user), provide the prompt to the second model 116 to cause the second model 116 to generate an output, such as a completion in response to the prompt, and present an indication of the output.

Referring further to FIG. 1, the system 100 can include at least one feedback trainer coupled with at least one feedback repository. The system 100 can use the feedback trainer to increase the precision and/or accuracy of the outputs generated by the second models 116 according to feedback provided by users of the system 100 and/or the applications 120.

The feedback repository can include feedback received from users regarding output presented by the applications 120. For example, for at least a subset of outputs presented by the applications 120, the applications 120 can present one or more user input elements for receiving feedback regarding the outputs. The user input elements can include, for example, indications of binary feedback regarding the outputs (e.g., good/bad feedback; feedback indicating the outputs do or do not meet the user’s criteria, such as criteria regarding technical accuracy or precision); indications of multiple levels of feedback (e.g., scoring the outputs on a predetermined scale, such as a 1-5 scale or 1-10 scale); freeform feedback (e.g., text or audio feedback); or various combinations thereof.

The system 100 can store and/or maintain feedback in the feedback repository. In some implementations, the system 100 stores the feedback with one or more data elements associated with the feedback, including but not limited to the outputs for which the feedback was received, the second model(s) 116 used to generate the outputs, and/or input information used by the second models 116 to generate the outputs (e.g., service request information; information captured by the user regarding the item of equipment).

The feedback trainer can update the one or more second models 116 using the feedback. The feedback trainer can be similar to the model updater 108. In some implementations, the feedback trainer is implemented by the model updater 108; for example, the model updater 108 can include or be coupled with the feedback trainer. The feedback trainer can perform various configuration operations (e.g., retraining, fine-tuning, transfer learning, etc.) on the second models 116 using the feedback from the feedback repository. In some implementations, the feedback trainer identifies one or more first parameters of the second model 116 to maintain as having predetermined values (e.g., freeze the weights and/or biases of one or more first layers of the second model 116), and performs a training process, such as a fine tuning process, to configure parameters of one or more second parameters of the second model 116 using the feedback (e.g., one or more second layers of the second model 116, such as output layers or output heads of the second model 116).

In some implementations, the system 100 may not include and/or use the model updater 108 (or the feedback trainer) to determine the second models 116. For example, the system 100 can include or be coupled with an output processor that can evaluate and/or modify outputs from the first model 104 prior to operation of applications 120, including to perform any of various post-processing operations on the output from the first model 104. For example, the output processor can compare outputs of the first model 104 with data from data sources 112 to validate the outputs of the first model 104 and/or modify the outputs of the first model 104 (or output an error) responsive to the outputs not satisfying a validation condition.

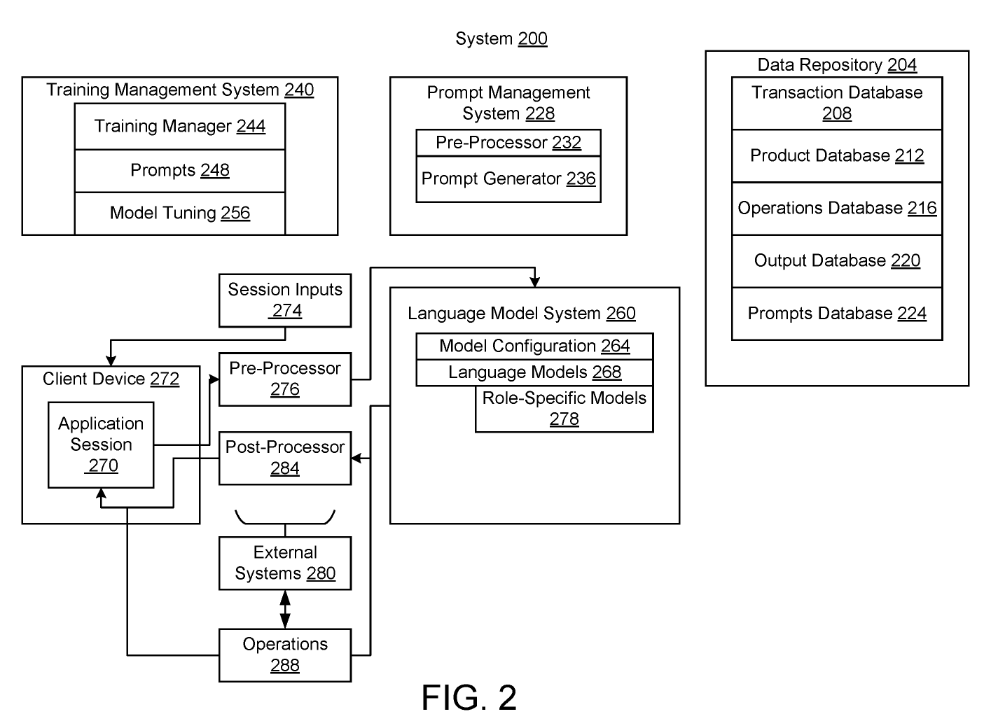

FIG. 2 depicts an example of a system 200. The system 200 can include one or more components or features of the system 100, such as any one or more of the first model 104, data sources 112, second model 116, and applications 120.

The system 200 can include at least one data repository 204, which can be similar to the data sources 112 described with reference to FIG. 1. The data repository 204 can include a transaction database 208, which can be similar or identical to one or more of warranty data or service data of data sources 112. For example, the transaction database 208 can include data such as parts used for service transactions; sales data indicating various service transactions or other transactions regarding items of equipment; warranty and/or claims data regarding items of equipment; and service data. The data repository 204 can include a product database 212, which can be similar or identical to the parts data of the data sources 112. The product database 212 can include, for example, data regarding products available from various vendors, specifications or parameters regarding products, and indications of products used for various service operations. The products database 212 can include data such as events or alarms associated with products; logs of product operation; and/or time series data regarding product operation, such as longitudinal data values of operation of products and/or building equipment. The data repository 204 can include an operations database 216, which can be similar or identical to the operations data of the data sources 112. For example, the operations database 216 can include data such as manuals regarding parts, products, and/or items of equipment; customer service data; and or reports, such as operation or service logs.

In some implementations, the data repository 204 can include an output database 220, which can include data of outputs that may be generated by various machine learning models and/or algorithms. For example, the output database 220 can include values of pre-calculated predictions and/or insights, such as parameters regarding operation items of equipment, such as setpoints, changes in setpoints, flow rates, control schemes, identifications of error conditions, or various combinations thereof. In some implementations, the data repository 204 can include a prompts database 224, which can include prompts that can be provided to various machine learning models and/or algorithms. For example, the prompts database 224 can include prompts that cause machine learning models to perform various operations.

The system 200 can include a prompt management system 228. The prompt management system 228 can process data from data repository 204 into training data for configuring various machine learning models, such as into a prompt and a completion corresponding to the prompt, based on the data from the data repository 204. In some implementations, the prompt management system 228 includes a pre-processor 232. The pre-processor 232 can perform any of various filtering, compression, tokenizing, or combining (e.g., combining data from various databases of the data repository 204) operations. The prompt management system 228 can include a prompt generator 236. The prompt generator 236 can generate, from data of the data repository 204, one or more training data elements that include a prompt and a completion corresponding to the prompt.

The system 200 can include a training management system 240. The training management system 240 can control training of machine learning models, including performing fine tuning and/or transfer learning operations. The training management system 240 can include a training manager 244. The training manager 244 can incorporate features of at least one of the model updater 108 or the feedback trainer described with reference to FIG. 1. In some implementations, the training management system 240 includes one or more prompts 248. For example, the training management system 240 can store one or more training data elements from the prompt management system 228. The training manager 244 can control the training of machine learning models using information or instructions maintained in a model tuning database 256. For example, the training manager 244 can store, in the model tuning database 256, various parameters or hyperparameters for models and/or model training.

The system 200 can include at least one model system 260 (e.g., one or more language model systems). The model system 260 can include model configurations 264 including one or more rules, heuristics, logic, policies, algorithms, functions, machine learning models, neural networks, scripts, or various combinations thereof to perform operations including configuring one or more machine learning models 268 based on instructions from the training management system 240.

The system 200 can implement at least one application session 270 for a client device 272. For example, responsive to configuring the machine learning models 268, the system 200 can generate data for presentation by the client device 272 (including generating data responsive to information received from the client device 272) using the at least one application session 270 and the one or more machine learning models 268. In some implementations, the system 200 provides data to the client device 272 for the client device 272 to operate the at least one application session 270. The application session 270 can include a session corresponding to any of the applications 120 described with reference to FIG. 1. For example, the client device 272 can launch the application session 270 and provide an interface to request one or more prompts. Responsive to receiving the one or more prompts, the application session 270 can provide the one or more prompts as input to the machine learning model 268. The machine learning model 268 can process the input to generate a completion, and provide the completion to the application session 270 to present via the client device 272. In some implementations, the application session 270 can iteratively generate completions using the machine learning models 268.

The system 200 can retrieve one or more session inputs 274 and/or be coupled with one or more sources of session inputs 274. The session inputs 274 can include, for example and without limitation, location-related inputs, such as identifiers of an entity managing an item of equipment or a building or building management system, a jurisdiction (e.g., city, state, country, etc.), a language, or a policy or configuration associated with operation of the item of equipment, building, building management system; an identifier of the user of the application session 270; and/or data regarding items of equipment or building management systems.

As depicted in FIG. 2, the system 200 can include at least one pre-processor 276. The pre-processor 276 can evaluate the prompt according to one or more criteria and pass the prompt to the model system 260 responsive to the prompt satisfying the one or more criteria, or modify or flag the prompt responsive to the prompt not satisfying the one or more criteria. The pre-processor 276 can compare the prompt with any of various predetermined prompts, thresholds, outputs of algorithms or simulations, or various combinations thereof to evaluate the prompt. The pre-processor 276 can evaluate the prompt according to values (e.g., numerical or semantic/text values) or thresholds for values to filter out of domain inputs, or filter out values that do not match target semantic concepts for the system 200. In some implementations, the pre-processor 276 retrieves context data to include (e.g., from the data repository 204 and/or external system 280) to include with the prompt of the application session 270 to generate the output provided to the application session 270. For example, the pre-processor 276 and/or language model system 260 can perform a retrieval augmented generation operation using data from the data repository.

As depicted in FIG. 2, in some implementations, the models 268 can include or otherwise be implemented as one or more role-specific models 278. The models 278 can be configured using training data (and/or have tuned hyperparameters) representative of particular tasks associated with generating accurate completions for the application sessions 270. For example, the models 278 can (iteratively) communicate with one another, such as based on language model job roles of the models 278, to refine results internally at the model system 260 (e.g., before/after communicating inputs/outputs with the application session 270), such as to validate completions and/or check confidence levels associated with completions.

Referring further to FIG. 2, the system 200 can include or be coupled with one or more external systems 280. The external systems 280 can include any of various data sources, algorithms, machine learning models, simulations, internet data sources, or various combinations thereof. The external systems 280 can be queried by the system 200 (e.g., by the model system 260) or the pre-processor 276 and/or post-processor 284, such as to identify thresholds or other baseline or predetermined values or semantic data to use for validating inputs to and/or outputs from the model system 260. The external systems 280 can include, for example and without limitation, documentation sources associated with an entity that manages items of equipment.

The system 200 can include at least one post-processor 284 (e.g., data validators). The post-processor 284 can modify data processed by the system 200 and/or triggering alerts responsive to the data not satisfying corresponding criteria, such as thresholds for values of data. The post-processor can be used to evaluate data relative to thresholds relating to data including, for example and without limitation, acceptable data ranges, setpoints, temperatures, pressures, flow rates (e.g., mass flow rates), or vibration rates for an item of equipment. The threshold can include any of various thresholds, such as one or more of minimum, maximum, absolute, relative, fixed band, and/or floating band thresholds. The post-processor 284 can enable the system 200 to detect when data, such as prompts, completions, or other inputs and/or outputs of the system 200, collide with thresholds that represent realistic behavior or operation or other limits of items of equipment. For example, the thresholds of the post-processor 284 can correspond to values of data that are within feasible or recommended operating ranges. In some implementations, the system 200 determines or receives the thresholds using models or simulations of items of equipment, such as plant or equipment simulators, chiller models, HVAC-R models, refrigeration cycle models, etc.

The system 200 can include or be coupled with operations data 288. The operations data 288 can be part of or analogous to one or more data sources of the data repository 204. The operations data 288 can include, for example and without limitation, data regarding real-world operations of building management systems and/or items of equipment, such as changes in building policies, building states, ticket or repair data, results of servicing or other operations, performance indices, or various combinations thereof. The operations data 288 can be retrieved by the application session 270, such as to condition or modify prompts and/or requests for prompts on operations data 288.

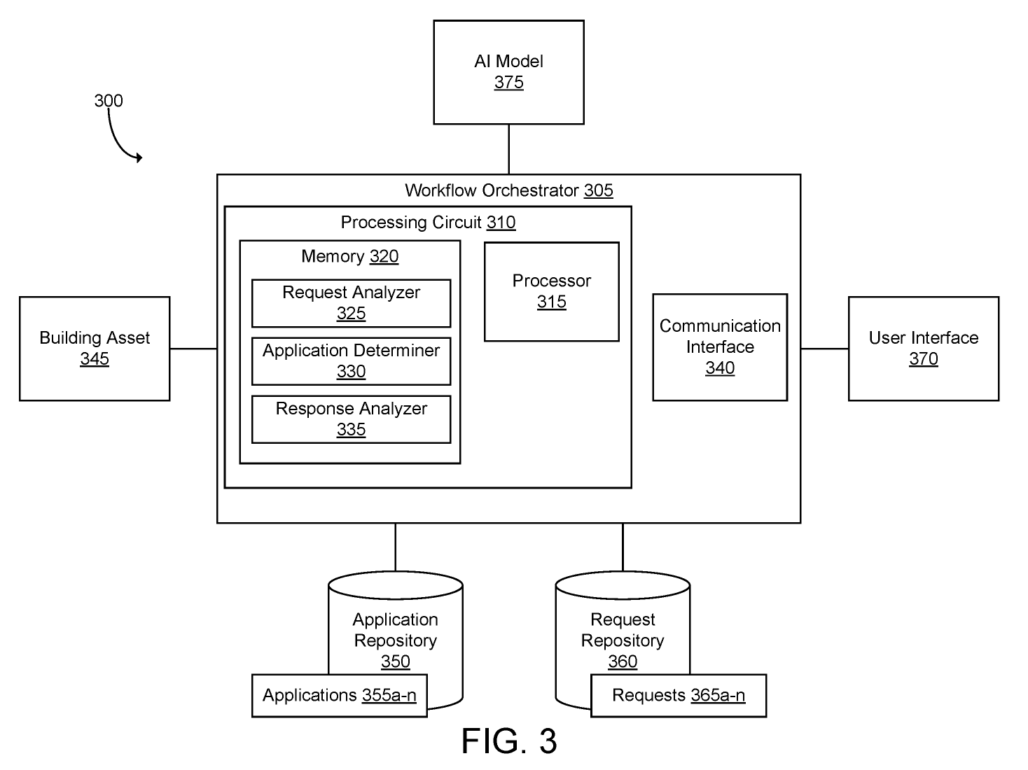

FIG. 3 depicts an example of a workflow orchestration system 300 for a building. The workflow orchestration system 300 is shown to include a workflow orchestrator 305. The workflow orchestrator 305 can receive requests (e.g., tasks, problems, etc.) related to assets (e.g., equipment, systems, software) of the building. Based on the requests, the workflow orchestrator 305 can identify one or more applications to handle (e.g., resolve, respond to) the request. The workflow orchestrator 305 can cause generation of a plan (e.g., solution) to handle (e.g., execute, complete, resolve) the request. The workflow orchestrator may perform operations including extracting relevant data, handle pre-processing of data, aggregating outputs, and/or generating custom responses to requests.

The workflow orchestrator 305 is shown to include at least one processing circuit 310, which may, as an example, include at least one processor 315 and at least one memory 320. The workflow orchestrator 305 may include one or more servers that include one or more of the processors and/or memory components described above and herein. The memory 320 can store computer-executable instructions that, when executed by the processor 315, cause the processor 315 to perform one or more of the operations described herein. The processor 315 may include a microprocessor, an application-specific integrated circuit (ASIC), a field-programmable gate array (FPGA), a graphics processing unit (GPU), a tensor processing unit (TPU), etc., and/or combinations thereof. The memory 320 may include, but is not limited to, electronic, optical, magnetic, or any other storage or transmission device capable of providing the processor 315 with program instructions. The memory 320 may further include a magnetic disk, memory chip, read-only memory (ROM), random-access memory (RAM), electrically erasable programmable ROM (EEPROM), erasable programmable ROM (EPROM), flash memory, optical media, or any other suitable memory from which the processor can read instructions. The instructions may include code from any suitable computer programming language. The workflow orchestrator 305 and/or the workflow orchestration system 300 can include one or more computing devices or servers that can perform various of the operations or functions described herein.

The memory 320 is shown to include a request analyzer 325. The request analyzer 325 can cause the processing circuit 310 to extract relevant information from requests received by the workflow orchestrator 305. For example, the request analyzer 325 can identify a prompt for an AI model embedded in the request, a task associated with the request, one or more applications referenced in the request, an expected response type (e.g., summary, report, file, structured data, recommendation, etc.) to the request and/or other relevant information relating to the request. The request analyzer 325 may further parse and interpret payloads, metadata, and/or files associated with the request and perform pre-processing operations such as validating request formats (e.g., determining that the request is of a valid type) or identifying request versions, among other operations. Responsive to a prompt for an AI model not being indicated in the request, the processing circuit 310 may generate a prompt based on other information of the request. For example, the processing circuit 310 may generate the prompt based on an inferred user intent, a task description indicated in the request, one or more referenced assets of the building, or historical request patterns, among other information. Additionally, or alternatively, the processing circuit 310 may generate the prompt to include system-level prompts tailored for the AI model. For example, the system-level prompts may include system-level instructions, application specifications, or system constraints, among other information.

The memory 320 is shown to include an application determiner 330. The application determiner 330 may include instructions that when executed by the processor 315, cause the processing circuit 310 to determine one or more applications to be used to complete the task identified in the request. In some embodiments, the processing circuit 310 can determine one or more applications based on an explicit reference the one or more applications in the request, such as an application identifier being included in the request. Responsive to the request analyzer 325 identifying one or more applications explicitly mentioned in the request, the application determiner 330 can determine whether the applications are available for use by the workflow orchestrator 305. In some embodiments, the processing circuit 310 can determine one or more applications based on other information included in the request. For example, the application determiner 330 may determine (e.g., infer) applications to be used to complete the request based on the task indicated in the request and/or historical application selections used for the same or similar tasks.

The memory 320 can include a response analyzer 335. The response analyzer 335 may include instructions that when executed by the processor 315, cause the processing circuit 310 to analyze responses to requests to determine whether the requests were properly handled (e.g., completed, executed, resolved). In some embodiments, the response analyzer 335 may analyze historical responses to requests to implement reinforcement learning and/or other processes to improve performance of the workflow orchestrator 305. In some embodiments, the response analyzer 335 can analyze responses in real time or near-real time (e.g., as requests are handled) so that responses returned (e.g., displayed, transmitted, etc.) to the operator (e.g., user, requestor) are accurate. Responsive to determining that a request was not handled properly (e.g., invalid and/or incorrect response), the response analyzer 335 can prevent the response from being returned to the operator and/or notify the operator that the response is invalid.

The workflow orchestrator 305 can include a communication interface 340. In some instances, the communication interface 340 includes, for example, program logic and any associated hardware components (e.g., transceivers, ethernet cards, etc.) that communicatively couples the workflow orchestrator 305 to any of building asset 345, an application repository 350, a request repository 360, a user interface 370, and/or an artificial intelligence (AI) model 375 (e.g., model 116, language model system 260). The communication interface 340 may communicate with or otherwise facilitate communication between components of the workflow orchestration system 300. In some embodiments, the communication interface 340 can communicate directly with systems and components described herein. In some embodiments, the communication interface can communicate indirectly (e.g., via a network, etc.) with systems and components described herein.

The workflow orchestration system 300 can include a user interface 370. The user interface 370 can be a device of a user, such as a technician or building manager. The user interface 370 can include any of various wireless or wired communication interfaces to communicate data with the workflow orchestrator 305, such as to provide requests to the workflow orchestrator 305 indicative of tasks for the AI model 375 to execute, and to receive outputs from the workflow orchestrator 305. The user interface 370 can include various user input and output devices to facilitate receiving and presenting inputs and outputs.

The workflow orchestration system 300 can include at least one building asset 345. The building asset 345 may be a may be a physical asset of the building (e.g., machine, system, object, etc.) and/or may be a digital asset (e.g., software, monitoring system, etc.). The building asset 345 may be communicatively coupled with the workflow orchestrator 305 and transmit data and/or requests (e.g., data requests, report requests, etc.) to the workflow orchestrator 305. The building asset 345 can receive communications and/or transmissions from the workflow orchestrator 305. For example, the building asset 345 can receive software updates, bug fixes, or other information from the workflow orchestrator 305. In some implementations, the building asset 345 may include the user interface 370, or may be communicatively coupled with the user interface 370 (e.g., either directly or indirectly) such that instructions entered via the user interface can be transmitted or routed to the building asset 345.

The workflow orchestration system 300 can include an application repository 350. The application repository 350 can store one or more applications 355a-n, referred to collectively as applications 355. The applications 355 include software to complete specific tasks relating to the workflow orchestrator 305 and/or the building asset 345. The applications 355 can complete tasks alone (e.g., singularly), and/or call (e.g., transmit an application programming interface (API) request to) other applications and/or models in the application repository 350 to complete tasks together. For example, a first application 355a can complete a first task alone and can interact with a second application 355b to complete a second task.

In some embodiments, the workflow orchestrator 305 can select (e.g., request, assign) one or more applications 355 to complete tasks. The application repository 350 can store each application 355 such that the workflow orchestrator 305 can request a respective application based on a unique identifier of the respective application 355. In some embodiments, the application repository 350 may store a group of applications 355 under a secondary (e.g., group) identifier. For example, each application 355 may include a first identifier that is a unique identifier for the respective application 355, and one or more second identifiers identifying one or more groups to which the respective application belongs. When the workflow orchestrator 305 selects a secondary identifier, the group of applications 355 can be retrieved rather than calling each application 355 of the group individually. For example, a first application 355a and a second application 355b having the same secondary identifier can both be retrieved when the workflow orchestrator 305 selects the secondary identifier of the first application 355a and the second application 355b.

In some embodiments, the applications 355 can use (e.g., call, request, prompt, etc.) one or more models (e.g., generative pre-trained transformer (GPT) models, language models, machine learning models) to complete tasks associated with each respective application 355. For example, the workflow orchestrator 305 can assign a task to an application 355, and the application 355 can use the one or more models to complete the task. In some implementations, the applications 355 may use the one or more models, without the workflow orchestrator 305 needing to select or request the one or more models separately. The application repository 350 can include information regarding the capabilities (e.g., functionalities) of each application 355. The information can include a task type (e.g., a category of tasks that the respective applications 355 can complete), identifiers (e.g., individual identifiers, group identifiers) of one or more applications 355 that can be called on (e.g., communicated with, requested) by the application 355, and/or one or more models that can be called on by the application 355. Additionally, or alternatively, the information may include parameters and/or constraints of the applications 355. For example, the information can indicate to the workflow orchestrator 305 that additional information (e.g., external information outside of the request) is needed to use an application 355.

In some embodiments, applications 355 may be added and/or removed from the application repository 350 without modifying other applications 355 of the application repository 350. For example, the workflow orchestrator 305 may add a first application 355a to the repository and configure the first application 355a to call (e.g., use) a second application 355b or model without adjusting features of the second application 355b. As another example, updates to applications 355 can be targeted to specific applications 355 such that only targeted applications 355 are impacted. According to an example implementation, the application repository 350 may include a first application 355a and a second application 355b. The first application 355a may include a first individual identifier and a first group identifier, and the second application 355b may include a second individual identifier and a second group identifier. When a third application 355c is added to the application repository 350, the third application 355c may include a third individual identifier, the first group identifier, and the second group identifier. As such, the association between the third application 355c, the first application 355a and the second application 355b may be established via the group identifiers rather than by modifying the first application 355a and the second application 355b. This may conserve computing resources that would otherwise be used to update the applications 355, and may make the application repository 350 more scalable as applications 355 are added and/or removed.

In some embodiments, there may a common (e.g., default, base) group of one or more applications 355 that is made available to the workflow orchestrator 305 to be used for all tasks. The common group can be used to complete tasks in a plurality of different cases, regardless of whether it was specifically called by the workflow orchestrator 305. For example, the workflow orchestrator 305 may use or call on a first application 355a and the applications 355 of the common group to complete a task responsive to a request indicating that a first application 355a should be used to complete the task. Additionally, or alternatively, the common group of applications 355 may be used to respond to tasks in cases where no application can be identified in the request. For example, if the application determiner 330 is unable to determine one or more applications best suited to respond to the request, the application determiner 330 may select the common group.

The workflow orchestration system 300 can include a request repository 360. The request repository 360 may be a database or other computer-readable storage media configured to store a plurality of requests 365a-n, referred to collectively as requests 365. The requests 365 can correspond to task requests made to the workflow orchestrator 305 (e.g., via the user interface 370 and/or building asset 345). The request repository 360 may include information relating to requests, including but not limited to identifiers of the requestor (e.g., building asset 345, operator, user interface 370), timestamps of the requests, prompt(s) identified or generated for the request, and/or applications selected to complete the request, among other information. In some embodiments, the request repository 360 can store or otherwise record responses regarding completion of the requests 365. The request repository 360 may store each request 365 and the corresponding response under a single identifier, such that requests 365 and responses can be retrieved simultaneously.

In some embodiments, the workflow orchestrator 305 can retrieve the requests 365 and/or the associated responses from the request repository 360 for display on the user interface 370. For example, the user interface 370 may display a prompt associated with the request and the response to the prompt generated by the applications 355. In some embodiments, the workflow orchestrator 305 can retrieve the requests 364 and/or the associated responses from the request repository 360 so that the workflow orchestrator can evaluate the performance of the applications 355 in completing tasks. For example, the workflow orchestrator 305 may determine that a prompt for a first request 365a performed better than a prompt for a second request 365b and can update (e.g., adjust, reconfigure, etc.) the workflow orchestrator 305 and/or the applications 355 to generate higher quality prompts and/or responses.

The workflow orchestration system 300 is shown to include an AI model 375. The AI model 375 can be a GPT model, or another model configured to receive a prompt associated with a request 365 from the workflow orchestrator 305. The prompt may include information relating to the request 365, including a description of a task, relevant datasets, a listing of applications 355 to be used to complete the task, an expected response to the task and/or other relevant information. In some embodiments, the prompts are pre-constructed (e.g., premade, templated) and are included in the request 365 transmitted to the workflow orchestrator 305. In some embodiments, the workflow orchestrator 305 can analyze the request 365 and generate or select a prompt based on information included in the request.

The AI model 375 can generate a plan for completing the task using the one or more applications 355 indicated in or selected based on the prompt. In some embodiments, the AI model 375 is constrained to generate a sequential structured plan (e.g., steps completed in a specific order) so that the workflow orchestrator 305 can properly execute the plan. For example, a first step may refer to loading data, a second step may refer to analyzing data, and a third step may refer to making decisions or generating responses based on the data. In some embodiments, the AI model 375 may generate the plan to include steps that can be executed in parallel (e.g., simultaneously), thereby improving a response time of the workflow orchestrator 305.

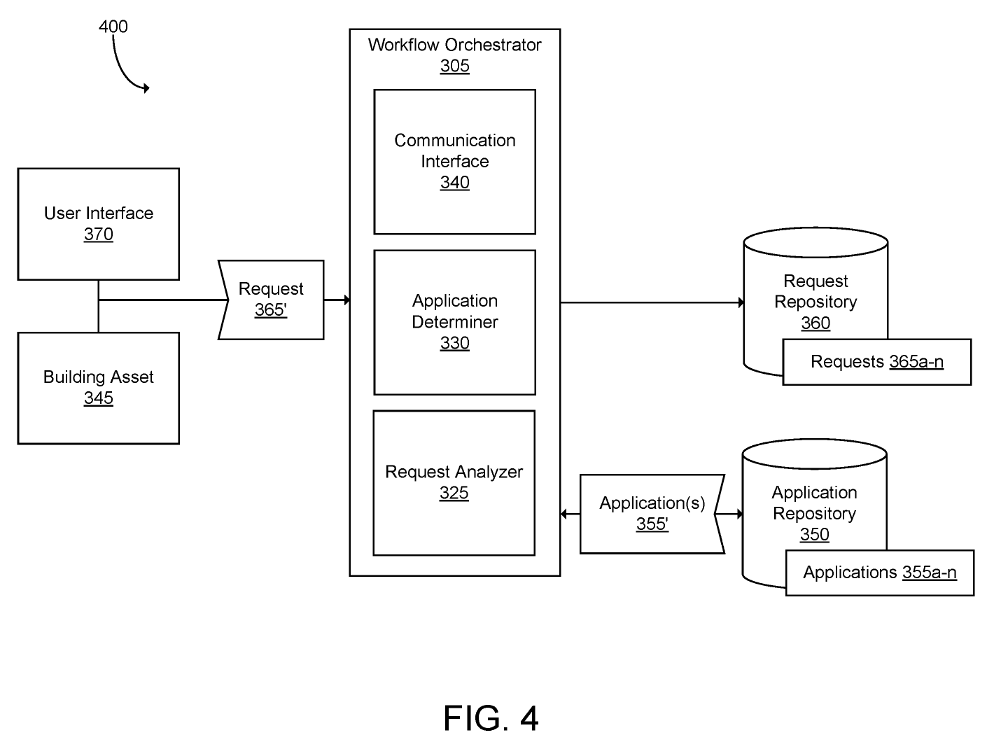

FIG. 4 depicts a workflow orchestration process 400 for processing requests and retrieving applications of the workflow orchestration system 300. Under the workflow orchestration process 400, at least one of the user interface 370 and/or the building asset 345 can transmit or provide a request 365’ to the workflow orchestrator 305. The request 365’ may be related or otherwise associated to the building asset 345. For example, the request 365’ may be a request for software updates, generating reports (e.g., forecasting, data analysis), bug fixes, maintenance requests, or other requests relating to the building asset 345.

The workflow orchestrator 305 can receive the request 365’ via the communication interface. Upon receiving the request, the request analyzer 325 may extract (e.g., pull, retrieve) relevant information from the request. For example, the request analyzer 325 may extract an identifier of the building asset 345, a timestamp of the request 365’, an urgency indicator of the request (e.g., for task prioritization), a task associated with the request 365’ to be completed by the workflow orchestrator 305, and identifiers of application 355 to be used to complete the request. In some embodiments, the request 365’ includes a pre-constructed prompt for transmission from the workflow orchestrator 305 (e.g., via the communication interface 340) to an AI model.

The workflow orchestrator 305 may store the request 365’ for storage in the request repository 360. The request repository 360 can store requests 365a-n handled (e.g., completed, resolved) by the workflow orchestrator 305 such that the workflow orchestrator 305, the user interface 370, and/or the building asset 345 can access information relating to the requests 365a-n.

The application determiner 330 can determine, based on information of the request 365’ at least one application 355’ to be called to complete the task indicated in the request 365’. In some embodiments, the at least one application 355’ is explicitly indicated in the request 365’. The application determiner 330 may search (e.g., parse, browse) the application repository 350 to check whether the at least one application 355’ is available for use by the workflow orchestrator 305. As described above, the at least one application 355’ may not be explicitly indicated in the request 365’. In such instances, the application determiner 330 can identify the proper applications 355’ to be used based on other information of the request 365’ and/or available applications in the application repository 350. For example, the application determiner 330 may search the request repository 360 for historical requests of the requests 365a-n that are similar to the request 365’, and identify which applications 355 were used to respond to the request. As another example, the application determiner 330 may select the common group of applications capable of responding to a variety of different types of requests.

In some embodiments, responsive to the at least one application 355’ not being present or available in the application repository 350, the workflow orchestrator 305 may determine whether a different application 355 can be used to complete the task. Responsive to determining that a second application 355 of the application repository 350 is able to complete the task and is available for use by the workflow orchestrator 305, the application determiner 330 may retrieve the second application 355 instead of the application 355’. Responsive to no available application 355 being able complete the task, the workflow orchestrator 305 may transmit a message for display on the user interface 370 indicating that the request 365’ cannot be resolved.

In some embodiments, the application 355’ includes multiple application versions. The application determiner 330 can determine or identify a version of the at least one application 355’ that is to be used to complete the task associated with the request. The application 355’ version may be identified in the request 365’ or may be determined by the application determiner 330 based on information included in the request 365’. The workflow orchestrator 305 or the application repository 350 can include (e.g., store) a unique route (e.g., path, identifier) to each application 355’ version, such that the workflow orchestrator 305 can separately access each application version. For example, the workflow orchestrator 305 may select the at least one application 355’ based on the plurality of versions for the at least one application 355’.

In some embodiments, the at least one application 355’ may be a group of applications and/or models (e.g., model 104, model 116). The application repository 350 can group applications 355 together based on shared characteristics or common task types performed to respond to requests. For example, a first group of applications may be grouped together because they are commonly used together for data forecasting. As another example, a second group of applications may be grouped together because they are commonly used for processing large datasets. In some embodiments, the application 355’ may include a common (e.g., default) application set that the workflow orchestrator 305 can call (e.g., retrieve) regardless of whether it is indicated in the request 365. The common application set may include one or more applications 355 that can be used to complete a variety of different tasks.

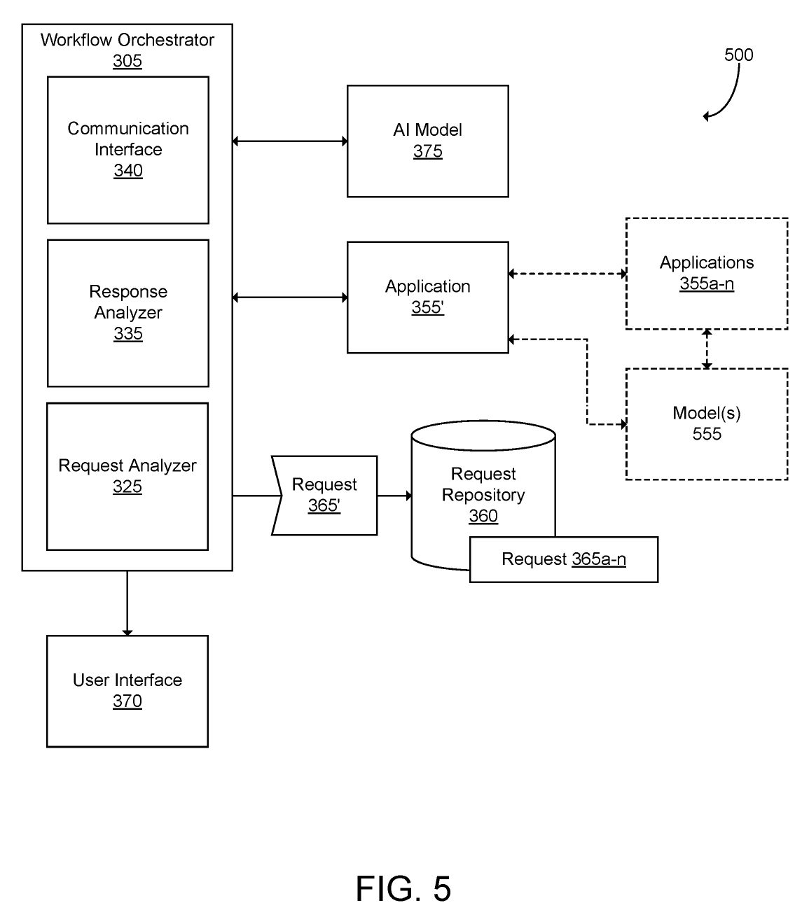

FIG. 5 a workflow orchestration process 500 for completing requests of the workflow orchestrator system 300. Under the workflow orchestration process 500, the workflow orchestrator 305 can submit a prompt to the AI model 375. The request analyzer 325 can analyze the request 365’ to determine (e.g., identify, generate) a prompt indicated in or selected based on the request 365’. The prompt can be a GPT-model readable request to cause the AI model 375 to generate a plan to execute one or more tasks of the request 365’.

In some instances, an artificial intelligence model, such as the AI model 375, may be used to orchestrate responding to requests rather than generating plans for responding to requests. For example, a system may prompt (e.g., via a first API request) an artificial intelligence model to generate a first operation for completing a first portion of the task to be completed by an application. In response to the application completing the first portion of the task, the system may prompt the artificial intelligence model again (e.g., via a second API request) to generate a second operation for completing a second portion of the task to be completed by an application. As such, the system may transmit a plurality of API requests to the artificial intelligence model to respond to a single request. These repeated API requests may result in excess computational resource consumption and/or increased latency associated with responding to requests. The workflow orchestration process 500 may reduce computational consumption and/or latency associated with responding to requests. Rather than using the AI model 375 to orchestrate responding to the request, the AI model 375 may only be prompted a single time to generate a plan to execute one or more tasks of the request. For example, the system may transmit a prompt to the AI model 375 indicating applications 355 and/or relationships between applications 355, and the AI model 375 can generate a full sequence of operations that can be performed using the applications 355 to respond to the request.

In some embodiments, the prompt is included (e.g., indicated, identified) in the request 365’. For example, the request analyzer 325 can identify the prompt based on a prompt identifier included in the request 365’. The request analyzer 325 may analyze the prompt to determine whether the prompt is valid (e.g., non-malicious). For example, the request analyzer 325 may include guardrails or other processes to determine that the prompt is valid, and does not pose certain cybersecurity risks, such as prompt injection attacks. In some embodiments, the prompt is not included or identified in the request 365’. The request analyzer 325 may analyze other information included in the request 365’ to determine (e.g., generate, select) a prompt for transmission to the AI model 375. For example, the request analyzer 325 may identify a task of the request 365’ and identify a prompt of a different request 365 in the request repository 360 corresponding to a similar task. As another example, the request analyzer 325 may identify a task of the request 365’ and generate a prompt corresponding to the task that the AI model 375 can process.

The workflow orchestrator 305 can transmit (e.g., via the communication interface 340) the prompt to the AI model 375. In some embodiments, the AI model 375 is a GPT model configured to receive the prompt and generate a sequential (e.g., step-by-step) plan (e.g., a sequence of operations) for completing the task identified in the prompt and responding to the request. The AI model 375 can process the prompt identify the at least one application 355’ that is selected to be used to complete the task. In some embodiments, the prompt indicates connections between the at least one application 355’ and other applications 355 and/or models 555 that the at least one application 355’ can call. In some embodiments, the AI model 375 is trained (e.g., taught, configured, pre-loaded, fine-tuned) to automatically identify connections between the application 355’ and other applications 355 and/or models 555 that the at least one application 355’ can call. As referred to herein, the models 555 may be deterministic or machine learning models (e.g., AI models, LLMs, transformer models) that the applications 355 can prompt (e.g., call) when performing tasks. For example, a first application 355a may be capable of accessing a first model 555, and a second application 355b may be capable of accessing a second model 555. In some implementations, the models 555 may be integrated into the applications. For example, the functionalities of the various models 555 may be inherent characteristics of one or more of the applications 355.

According to an example implementation, the workflow orchestrator 305 may transmit a prompt to the AI model 375. The prompt may identify the at least one application 355’ and information associated with the task to be completed by the at least one application 355’. The prompt may include information (e.g., individual identifiers, group identifiers, etc.) associated with the at least one application 355’, such that the AI model 375 can identify one or more other applications 355 or models 555 that the at least one application 355’ can call (e.g., prompt, communicate with, request, etc.). The prompt may instruct the AI model 375 to generate a plan using the at least one application 355’ to complete the task indicated in the prompt. For example, the plan may include instructions to perform data pre-processing operations, perform calculations, perform post-processing operations, generate content, and/or generate user interface displays, among other instructions. In some cases, the plan may include instructions to call one or more other applications 355 or models 555 to perform tasks in sequence or in parallel with the at least one application 355’. For example, the plan may instruct the at least one application 355’ to perform a calculation, provide a result of the calculation to a different application 355, and receive an output of the different application 355.

Upon receiving the plan from the AI model 375, the workflow orchestrator 305 can execute or otherwise complete the plan using the application 355’. The workflow orchestrator 305 can call on the application 355’ to complete the plan. The workflow orchestrator 305 can provide the application 355’ with other information (e.g., files, datasets, etc.) needed to execute the plan. In some embodiments, the application 355’ can complete each step (e.g., part) of the plan without returning information to the workflow orchestrator 305. For example, the application 355’ may complete each step, and only return a final result of the plan to the workflow orchestrator 305. In some embodiments, the application 355’ can complete each step (e.g., part) of the plan, and subsequently return a result (e.g., notification, communication) to the workflow orchestrator 305 indicating that the step was executed before continuing with the next step.

As described above, the application 355’ may be communicatively coupled with other applications 355 and/or models 555. The application 355’ may call on or otherwise assign tasks to other applications 355 and/or models 555 without explicit instruction from the workflow orchestrator 305. For example, based on the plan, the application 355’ may identify other applications 355 and/or models 555 that the application 355’ is to call on to execute the plan. As such, the plan may be structured such that once the application 355’ initiates the plan, the application 355’ coordinates (e.g., orchestrates) execution of the plan without further involvement by the workflow orchestrator 305.

The application 355’ can return a response (e.g., final result of the plan) to the workflow orchestrator 305. The response analyzer 335 can process the response to determine whether the plan was properly executed (e.g., the task indicated in the request was properly completed). Responsive to determining that the plan was properly executed, the request analyzer 325 may update a status of the request 365’ on the user interface 370 indicating that the plan was successfully executed. Responsive to the plan not being properly executed, the request analyzer 325 may update a status of the request 365’ on the user interface 370 indicating that the plan was not successfully executed. The workflow orchestrator 305 may transmit and/or display information (e.g., reports, forecasts, conclusions, updates, etc.) from the application 355’ to the user interface 370 in accordance with the response returned to the workflow orchestrator 305 from the application 355’. In some embodiments, the request analyzer 325 may transform the response from the application into a human-readable format before displaying it on the user interface 370. For example, the request analyzer 325 may receive a response including raw data in a computer-readable format, and generate a report (e.g., document, graphic, etc.) based on the response and provide the user interface 370 with access to the report.

The workflow orchestrator 305 can generate an association between the response and the request 365’, and subsequently store the request 365’ in the request repository 360 with its associated response. The workflow orchestrator 305 can retrieve the request 365’ and response and/or other requests 365 from the request repository 360 to evaluate overall performance of the workflow orchestrator 305, AI model 375, and/or applications 355 in completing requests. The workflow orchestrator 305 may perform post-processing (e.g., via post-processor 284) on the request 365’ or a plurality of requests 365, and update the workflow orchestrator 305, AI model 375, applications 355 and/or models 555 based on determinations made during post-processing. For example, responsive to the post-processor 284 determining that a plurality of requests 365 that use the same application 355a had invalid (e.g., incorrect) responses, the post-processor may cause the application 355a to be updated or otherwise adjusted.

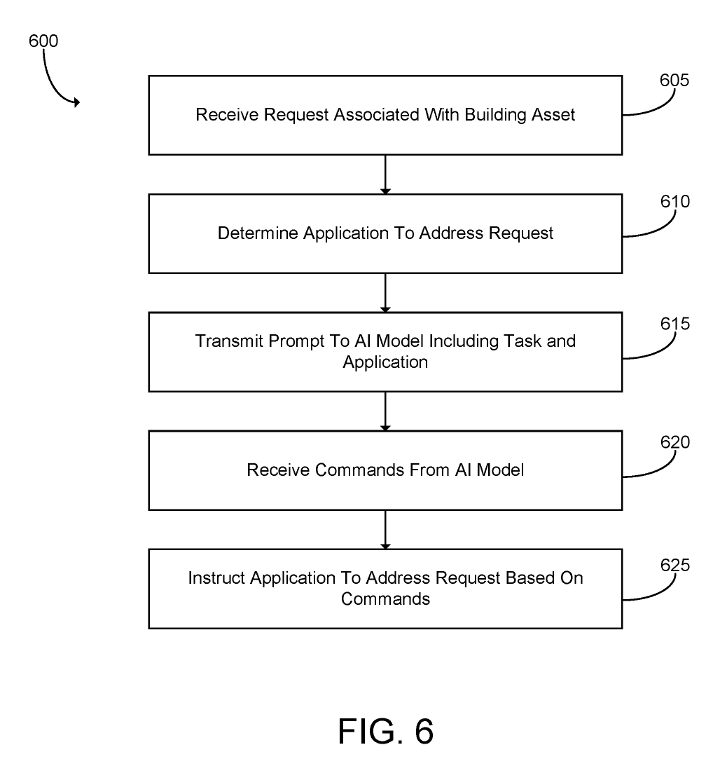

FIG. 6 depicts a flow diagram of an example method 600 for completing a request using the workflow orchestration system 300. At step 605, one or more processors (e.g., of the workflow orchestrator 305) can receive a request associated with the building asset 345. In some embodiments, the building asset 345 is a piece of building equipment (e.g., machine, system, etc.) of a building or a digital system (e.g., monitoring system, sensor system, cooling system, heating system, etc.) of the building. The request may be sent (e.g., transmitted, requested) by the building asset 345 automatically, or may be sent by an operator of the building asset 345 responsive to an interaction with the user interface 370.

In some embodiments, the one or more processors may analyze (e.g., search, scan) the request for certain information included in the request. For example, the one or more processors may extract information from the request relating to at least one task, an identifier of the building asset 345, a timestamp of the request, an urgency status of the request, one or more applications 355 of the system 300 that can be used to complete the request, among other information included in or associated with the request. The information of the request may be identified by the one or more processors based on identifiers (e.g. headers) of the information and/or based on the content of the request (e.g., using keyword matching, semantic analysis, natural language processing, etc.).

At step 610, the one or more processors can determine (e.g., select, identify, etc.) at least one application 355 to use to address (e.g., respond to) the request. In some embodiments, the one or more processors may determine the application 355 based on information included in the request. For example, the request may include an indication (e.g., identifier) of an application 355 to be used to address the request. In some embodiments, the one or more processors may determine the application 355 based on similar characteristics between the request and historical requests. For example, the one or more processors may search the request repository 360 to identify similar requests. The one or more processors may determine whether the determined application 355 is available to be used to address the request. For example, application repository 350 may include availability indicators for each application 355 indicating whether a respective application 355 is available for use, and the one or more processors may search the application repository 350 for the availability indicators to determine whether the application 355 is available for use.

At step 615, the one or more processors can transmit a prompt to the AI model 375. The prompt may include at least one task of the request to be completed by the application 355, and may identify the application 355 to be used to complete the task. The AI model 375 can be configured (e.g., trained) to identify capabilities of the application 355. For example, the AI model 375 may identify tasks that the application 355 can complete and/or other applications 355 or models 555 that the application can call on. Based on the prompt, the AI model 375 can generate a plan corresponding to the prompt configured to complete the task. In some embodiments, the plan is a sequential (e.g., step-by-step) plan configured to be executed by the application 355 in a specific order. In some embodiments, the plan includes steps that can be completed either sequentially and/or simultaneously.

At step 620, the one or more processors can receive a set of commands (e.g., instructions) representing a sequence of operations from the AI model 375 corresponding to the plan. The one or more processors may identify (e.g., extract) each step (e.g., command) of the plan based on the response from the AI model 375. For example, responsive to the AI model 375 returning a code file to the one or more processors, the one or more processors can extract each individual step from the code file. The commands may include reference to specific applications 355 that should be assigned to each command. For example, a first command may indicate assignment to a first application 355a, and a second command may indicate assignment to a second application 355b. The commands may include references to external data (e.g., files, datasets, etc.) that should be provided to the applications to perform the command. For example, based on whether a command involves processing a dataset, the command may include the name of the dataset and/or a route for the application 355 to access the dataset.

At step 625, the one or more processors can instruct the application 355 to address the request based on the commands. For example, the one or more processors may generate an instruction based on the commands for the application 355 to address the request. The one or more processors may perform other tests and/or checks to ensure that the application 355 successfully receives and executes the commands. The application 355 may perform the task alone, or may call on or otherwise assign tasks to other applications 355 and/or models 555 (e.g., based on the plan generated by the AI model 375). In some implementations, the one or more processors may instruct the application 355 based on the selected application version of the application 355. For example, if a first version of the application 355 is selected, the one or more processors may generate a first instruction for the application. As another example, if a second version of the application 355 is selected, the one or more processors may generate a second instruction for the application 355.

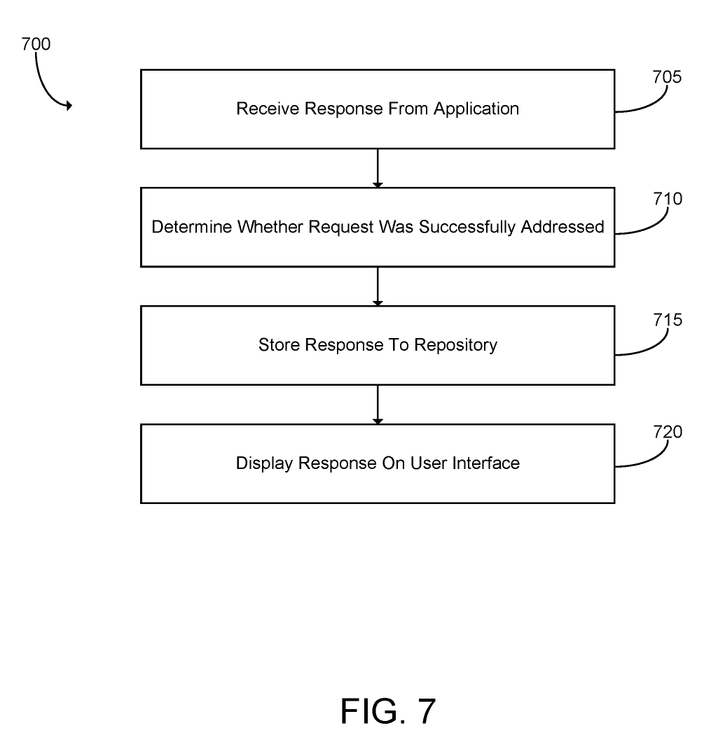

FIG. 7 depicts a flow diagram of an example method 700 for completing a request using the workflow orchestration system 300. In some embodiments, the method 700 can be completed subsequently to the method 600. In some embodiments, the method 700 can be completed separately from the method 600. At step 705, one or more processors (e.g., of the workflow orchestrator 305) can receive a response from an application 355. The response may correspond to completion of a task indicated in a request received by the one or more processors. In some embodiments, the response is a report (e.g., forecast, summary, etc.) relating to performance of the building asset 345. As an example, the response may be a report-based response, such as an emissions forecast for a piece of building equipment. In some embodiments, the response may be an action-based response, such as deploying software updates and/or adjusting settings of the building asset 345.

At step 710, the one or more processors can determine whether the request (e.g., the task) was successfully addressed by the response. In some embodiments, the one or more processors may test the response to determine whether the response matches an expected response. For example, responsive to the response being a forecast report, the one or more processors may compare the forecast report to a historical forecast report (e.g., stored in the request repository 360) to determine that the forecast reports are similar. As another example, responsive to the expected response being an emissions report, the one or more processors may analyze the response to determine that the response is an emissions report and not a different type of report. Responsive to the one or more processors determining or identifying that the response is invalid (e.g., improper, incorrect), the one or more processors may display a message on the user interface 370 indicating an invalid response.

At step 715, the one or more processors can store the response in the request repository 360. The one or more processors may append or otherwise associate (e.g., via an identifier) the response to the request associated with the response and store both the request and the response in the request repository 360. The one or more processors may retrieve requests and/or responses from the request repository 360 to evaluate performance of the workflow orchestrator 305, the AI model 375, and/or the applications 355. For example, responsive to the one or more processors determining that multiple requests resolved or otherwise completed by an application 355 resulted in invalid responses, the one or more processors may indicate that the application 355 is defective and should be fixed (e.g., updated). As another example, responsive to the one or more processors determining that multiple commands generated by the AI model 375 resulted in invalid responses, the one or more processors may indicate that the AI model 375 should be updated (e.g., retrained, reinforced, etc.)

At step 720, the one or more processors can display the response on the user interface 370. In some embodiments, the one or more processors can convert (e.g., transform) the response into a human-readable format (e.g., text). For example, responsive to the response being raw forecast data, the one or more processors may use the data to generate a report that an operator (e.g., user) can interact with. In some embodiments, the one or more processors can display a notification to the user interface 370 that the request has been fulfilled (e.g., executed, completed, handled, resolved). For example, responsive to the response being a software update and/or settings adjustment for the building asset 345, the one or more processors may display a notification on the user interface that the update/adjustment has been uploaded on the building asset 345.

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

In various implementations, the steps and operations described herein may be performed on one processor or in a combination of two or more processors. For example, in some implementations, the various operations could be performed in a central server or set of central servers configured to receive data from one or more devices (e.g., edge computing devices/controllers) and perform the operations. In some implementations, the operations may be performed by one or more local controllers or computing devices (e.g., edge devices), such as controllers dedicated to and/or located within a particular building or portion of a building. In some implementations, the operations may be performed by a combination of one or more central or offsite computing devices/servers and one or more local controllers/computing devices. All such implementations are contemplated within the scope of the present disclosure. Further, unless otherwise indicated, when the present disclosure refers to one or more computer-readable storage media and/or one or more controllers, such computer-readable storage media and/or one or more controllers may be implemented as one or more central servers, one or more local controllers or computing devices (e.g., edge devices), any combination thereof, or any other combination of storage media and/or controllers regardless of the location of such devices.

What is claimed is:

1. A system for configurating building workflows, comprising one or more memory devices storing instructions thereon that, when executed by one or more processors, cause the one or more processors to:
receive a request associated with operation of a building asset;
determine, based on the request, one or more applications to be executed to address the request;
cause an artificial intelligence model to generate commands representing a sequence of operations for the one or more applications to address the request; and
instruct the one or more applications to address the request based on the commands.

2. The system of claim 1, wherein the one or more applications are configured to cause a model to address the request based on the commands.

3. The system of claim 1 wherein the instructions cause the one or more processors to:
receive a response from the one or more applications, the response comprising information associated with addressing the request;
determine, based on the response, whether the request was resolved; and
update at least one of (a) the artificial intelligence model or (b) the one or more applications based on whether the request was resolved.

4. The system of claim 3, wherein the instructions cause the one or more processors to:
store the request and the response in a request repository; and
cause the request and the response to be displayed on a user interface.

5. The system of claim 1, wherein the instructions cause the one or more processors to:
determine whether the request is of a valid type; and
determine whether the one or more applications were successful in addressing the request.

6. The system of claim 1, wherein instructions cause the one or more processors to receive the request responsive to at least one of (i) a transmission of the request caused by an interaction with a user interface, or (ii) a transmission of the request transmitted by the building asset.

7. The system of claim 1, wherein the instructions cause the one or more processors to select the one or more applications by:
identifying, based on the request, the one or more applications from an application repository to be executed to address the request; and
retrieving, from the application repository, the one or more applications.

8. The system of claim 1, wherein the instructions cause the one or more processors to cause generation of commands by:
generating an prompt for the artificial intelligence model, the prompt indicating the request and the one or more applications; and
transmitting the prompt to the artificial intelligence model.

9. The system of claim 1, wherein the instructions cause the one or more processors to instruct the one or more applications by:
receiving the commands representing a sequence of operations from the artificial intelligence model; and
generating, based on the commands, an instruction for the one or more applications to address the request.

10. The system of claim 1, wherein the one or more applications comprise a plurality of application versions, wherein the instructions cause the one or more processors to:
select the one or more applications based on the plurality of application versions; and
instruct the one or more applications to address the request based on the selected application version.

11. A method of building language model workflow configuration, comprising:
receiving, by one or more processors, a request associated with operation of a building asset;
selecting, by the one or more processors, based on the request, one or more applications to be executed to address the request;
causing, by the one or more processors, generation of commands representing a sequence of operations for the one or more applications to address the request; and
instructing, by the one or more processors, the one or more applications to address the request based on the commands.

12. The method of claim 11, further comprising:
determining, by the one or more processors, whether the request is of a valid type; and
determining, by the one or more processors, whether the one or more applications were successful in addressing the request.

13. The method of claim 11, wherein selecting the one or more applications comprises:
identifying, by the one or more processors, based on the request, the one or more applications to be executed to address the request; and
retrieving, by the one or more processors, the one or more applications.

14. The method of claim 11, wherein causing generation of commands comprises:
generating, by the one or more processors, an prompt for an artificial intelligence model, the prompt indicating the request and the one or more applications; and
transmitting, by the one or more processors, to the artificial intelligence model, the prompt.

15. The method of claim 11, wherein the commands are generated by an artificial intelligence model, further comprising:
receiving, by the one or more processors, a response from the one or more applications, the response comprising information associated with addressing the request;
determining, by the one or more processors, based on the response, whether the request was resolved; and
updating, by the one or more processors, at least one of (a) the artificial intelligence model or (b) the one or more applications based on whether the request was resolved.

16. The method of claim 15, wherein instructing the one or more applications comprises:
receiving, by the one or more processors, the commands representing a sequence of operations from the artificial intelligence model; and
generating, by the one or more processors, based on the commands, an instruction for the one or more applications to address the request.

17. The method of claim 15, further comprising:
storing, by the one or more processors, the request and the response in a request repository; and
causing, by the one or more processors, the request and the response to be displayed on a user interface.

18. One or more non-transitory storage media storing instructions thereon that, when executed by one or more processors, cause the one or more processors to perform operations comprising:
receive a request associated with operation of a building asset;
select, based on the request, one or more applications to be executed to address the request;
cause generation of commands representing a sequence of operations for the one or more applications to address the request; and
instruct the one or more applications to address the request based on the commands.

19. The one or more non-transitory storage media of claim 18, wherein the instructions cause the one or more processors to cause generation of commands by:
generating an prompt for an artificial intelligence model, the prompt indicating the request and the one or more applications; and
transmitting the prompt to the artificial intelligence model.

20. The one or more non-transitory storage media of claim 18, wherein the commands are generated by an artificial intelligence model, wherein the instructions cause the one or more processors to:
receive a response from the one or more applications, the response comprising information associated with addressing the request;
determine, based on the response, whether the request was resolved; and
update at least one of (a) the artificial intelligence model or (b) the one or more applications based on whether the request was resolved.
